(19) United States
(12) Patent Application Publication
(10) Pub. No.: US 2021/0366662 A1
(43) Pub. Date: Nov. 25, 2021

(54) SOLAR CELL MODULE

(71) Applicant: RICOH COMPANY, LTD., Tokyo (JP)

(72) Inventors: Tamotsu HORIUCHI, Shizuoka (JP); Nozomu TAMOTO, Shizuoka (JP); Takahiro IDE, Shizuoka (JP); Yuuji TANAKA, Shizuoka (JP); Naomichi KANEI, Shizuoka (JP)

(21) Appl. No.: 17/277,115

(22) PCT Filed: Sep. 25, 2019
(86) PCT No.: PCT/JP2019/037651

§ 371 Date: Mar. 17, 2021

(30) Foreign Application Priority Data
Sep. 28, 2018 (JP) 2018-183343

(51) Int. Cl. H01G 9/20; H01L 51/42; H01L 51/44

(52) U.S. Cl. CPC H01G 9/2009; H01G 9/2077; H01L 51/448; H01L 51/4293; H01L 51/442; H01L 51/4253

(57) ABSTRACT

A solar cell module (100) including: a substrate (1); and a plurality of photoelectric conversion elements disposed on the substrate (1), each of the plurality of photoelectric conversion elements including a first electrode (2a, 2b), an electron transport layer (3, 4), a perovskite layer (5), a hole transport layer (6), and a second electrode (7a, 7b), wherein, within at least two of the photoelectric conversion elements adjacent to each other, the hole transport layers (6) are continuous with each other, and the first electrodes (2a, 2b), the electron transport layers (3, 4), and the perovskite layers (5) are separated by the hole transport layer (6) within the at least two of the photoelectric conversion elements adjacent to each other.

### TECHNICAL FIELD

The present disclosure relates to a solar cell module.

### BACKGROUND ART

In recent years, solar cells using a photoelectric conversion element have been expected to be widely applied not only in terms of alternative to fossil fuels and measures against global warming but also as self-supporting power supplies that require neither replacement of battery nor power source wirings. Moreover, the solar cells as the self-supporting power supplies attract much attention as one of energy harvesting techniques required in IoT (internet of things) devices or artificial satellites.

The solar cells include organic solar cells such as dye-sensitized solar cells, organic thin film solar cells, and perovskite solar cells, as well as inorganic solar cells using silicon that have been widely conventionally used. The perovskite solar cells are advantageous in terms of improvement of safety and inhibition of production cost, because they can be produced with the conventionally existing printing units without using an electrolyte containing, for example, iodine or an organic solvent.

Regarding the organic thin film solar cells and the perovskite solar cells, it is known that a plurality of photoelectric conversion elements that are spatially separated are electrically connected so as to form a series circuit to increase output voltage (see, for example, PTL 1).

In addition, regarding the perovskite solar cells, an aspect where a porous titanium oxide layer (electron transport layer) or a perovskite layer in a plurality of photoelectric conversion elements is extended (continuous) is also known.

### CITATION LIST

### Patent Literature

PTL 1: Japanese Unexamined Patent Application Publication No. 2016-195175

### SUMMARY OF INVENTION

### Technical Problem

An object of the present disclosure is to provide a solar cell module that can maintain power generation efficiency even after exposure to light having a high illuminance for a long period of time.

### Solution to Problem

A solar cell module of the present disclosure as a means for achieving the aforementioned object includes: a substrate; and a plurality of photoelectric conversion elements disposed on the substrate. Each of the plurality of photoelectric conversion elements includes a first electrode, an electron transport layer, a perovskite layer, a hole transport layer, and a second electrode. Within at least two of the photoelectric conversion elements adjacent to each other, the hole transport layers are continuous with each other. The first electrodes, the electron transport layers, and the perovskite layers are separated by the hole transport layer within the at least two of the photoelectric conversion elements adjacent to each other.

### Advantageous Effects of Invention

According to the present disclosure, it is possible to provide a solar cell module that can maintain power generation efficiency even after exposure to light having a high illuminance for a long period of time.

### BRIEF DESCRIPTION OF DRAWINGS

FIG. 1 is a cross-sectional view illustrating one example of a cross-sectional structure of a solar cell module of the present disclosure.

FIG. 2 is a cross-sectional view illustrating another example of a cross-sectional structure of the solar cell module of the present disclosure.

FIG. 3 is a cross-sectional view illustrating one example of a cross-sectional structure of a solar cell module of Comparative Example of the present disclosure.

FIG. 4 is a cross-sectional view illustrating another example of a cross-sectional structure of a solar cell module of Comparative Example of the present disclosure.

FIG. 5 is a cross-sectional view illustrating another example of a cross-sectional structure of a solar cell module of Comparative Example of the present disclosure.

### DESCRIPTION OF EMBODIMENTS

(Solar Cell Module)

A solar cell module of the present disclosure includes: a substrate; and a plurality of photoelectric conversion elements disposed on the substrate. Each of the plurality of photoelectric conversion elements includes a first electrode, an electron transport layer, a perovskite layer, a hole transport layer, and a second electrode. Within at least two of the photoelectric conversion elements adjacent to each other, the hole transport layers are continuous with each other. The first electrodes, the electron transport layers, and the perovskite layers are separated by the hole transport layer within the at least two of the photoelectric conversion elements adjacent to each other.

A solar cell module of the present disclosure is based on the fact that the existing solar cell modules having perovskite layers drastically decrease power generation efficiency after exposure to light having a high illuminance for a long period of time. Specifically, in the existing solar cell modules having perovskite layers, because a porous titanium oxide layer (electron transport layer) or a perovskite layer is extended, such a configuration causes much recombination of electrons through diffusion and drastically decreases power generation efficiency after exposure to light having a high illuminance for a long period of time, which is problematic.

Meanwhile, regarding the solar cell module of the present disclosure, the hole transport layers are continuous with each other, and the first electrodes, the electron transport layers, and the perovskite layers are separated by the hole transport layer within the at least two of the photoelectric conversion elements adjacent to each other. Therefore, the solar cell module of the present disclosure has porous titanium oxide layers (electron transport layers) and perovskite layers that are separated and causes less recombination of electrons through diffusion, which makes it possible to maintain power generation efficiency even after exposure to light having a high illuminance for a long period of time.

A solar cell module of the present disclosure includes a substrate and a plurality of photoelectric conversion elements disposed on the substrate, preferably further includes a second substrate different from the aforementioned substrate and a sealing member, and includes other members if necessary.

<Substrate>

A shape, a structure, and a size of the substrate are not particularly limited and may be appropriately selected depending on the intended purpose. Note that, the aforementioned substrate may be referred to as a “first substrate” hereinafter.

A material of the first substrate is not particularly limited and may be appropriately selected depending on the intended purpose, so long as it has translucency and insulation. Examples thereof include glass, plastic films, and ceramics. Among them, in the case where a baking step of forming an electron transport layer as described below is included, a material having heat resistance to a baking temperature is preferable. Moreover, preferable examples of the first substrate include those having a flexibility.

<Photoelectric Conversion Element>

The photoelectric conversion element means an element that can convert light energy into electric energy and is applied to, for example, solar cells and photodiodes.

The photoelectric conversion element in the present disclosure includes at least a first electrode, an electron transport layer, a perovskite layer, a hole transport layer, and a second electrode.

<<First Electrode>>

A shape and a size of the first electrode are not particularly limited and may be appropriately selected depending on the intended purpose, so long as the first electrodes within at least two photoelectric conversion elements adjacent to each other are separated by a hole transport layer that will be described hereinafter.

A structure of the first electrode is not particularly limited and may be appropriately selected depending on the intended purpose. The structure of the first electrode may be a single layer structure or a structure where a plurality of materials are laminated.

A material of the first electrode is not particularly limited and may be appropriately selected depending on the intended purpose, so long as the material is a material having conductivity. Examples thereof include transparent conductive metal oxides, carbon, and metals.

Examples of the transparent conductive metal oxide include indium-tin oxide (referred to as “ITO” hereinafter), fluorine-doped tin oxide (referred to as “FTO” hereinafter), antimony-doped tin oxide (referred to as “ATO” hereinafter), niobium-doped tin oxide (referred to as “NTO” hereinafter), aluminum-doped zinc oxide, indium-zinc oxide, and niobium-titanium oxide.

Examples of the carbon include carbon black, carbon nanotube, graphene, and fullerene.

Examples of the metal include gold, silver, aluminum, nickel, indium, tantalum, and titanium.

These may be used alone or in combination. Among them, transparent conductive metal oxide having high transparency is preferable, ITO, FTO, ATO, and NTO are more preferable.

An average thickness of the first electrode is not particularly limited and may be appropriately selected depending on the intended purpose. The average thickness of the first electrode is preferably 5 nm or more but 100 micrometers or less, more preferably 50 nm or more but 10 micrometers or less. When a material of the first electrode is carbon or metal, the average thickness of the first electrode is preferably an average thickness enough for obtaining translucency.

The first electrode can be formed by known methods such as sputtering, vapor deposition, and spraying.

Moreover, the first electrode is preferably formed on the first substrate. It is possible to use an integrated commercially available product where the first electrode has been formed on the first substrate in advance.

Examples of the integrated commercially available product include FTO coated glass, ITO coated glass, zinc oxide/aluminum coated glass, an FTO coated transparent plastic film, and an ITO coated transparent plastic film. Other examples of the integrated commercially available product include glass substrates provided with a transparent electrode where tin oxide or indium oxide is doped with a cation or an anion having a different atomic value and glass substrates provided with a metal electrode having such a structure that allows light in the form of a mesh or stripes to pass.

These may be used alone, or two or more products may be used in combination as a combined product or a laminate. Moreover, a metal lead wire may be used in combination in order to decrease an electric resistance value.

A material of the metal lead wire is, for example, aluminum, copper, silver, gold, platinum, and nickel.

The metal lead wire is used in combination by forming it on the substrate through, for example, vapor deposition, sputtering, or pressure bonding, and disposing a layer of ITO or FTO thereon.

<<Electron Transport Layer>>

The electron transport layer means a layer that transports, to the first electrode, electrons generated in a perovskite layer that will be described hereinafter. Therefore, the electron transport layer is preferably disposed next to the first electrode.

A shape and a size of the electron transport layer are not particularly limited and may be appropriately selected depending on the intended purpose, so long as the electron transport layers within at least two photoelectric conversion elements adjacent to each other are separated by a hole transport layer that will be described hereinafter.

A structure of the electron transport layer may be a single layer or a multilayer formed by laminating a plurality of layers. However, the structure thereof is preferably a multilayer. The structure thereof is more preferably formed of a layer having a compact structure (compact layer) and a layer having a porous structure (porous layer). In addition, the compact layer is preferably disposed closer to the first electrode than the porous layer.

<<<Compact Layer>>>

The compact layer is not particularly limited and may be appropriately selected depending on the intended purpose, so long as it includes an electron transport material and is more compact than a porous layer that will be described hereinafter. Here, being more compact than the porous layer means that a packing density of the compact layer is higher than a packing density of particles forming the porous layer.

The electron transport material is not particularly limited and may be appropriately selected depending on the intended purpose, but is preferably a semiconductor material.

The semiconductor material is not particularly limited and known materials may be used. Examples of the semiconductor material include single semiconductors and compounds having compound semiconductors.

Examples of the single semiconductor include silicon and germanium.

Examples of the compound having the compound semiconductor include chalcogenide of metal. Specific examples thereof include: oxides of titanium, tin, zinc, iron, tungsten, zirconium, hafnium, strontium, indium, cerium, yttrium, lanthanum, vanadium, niobium, and tantalum; sulfides of cadmium, zinc, lead, silver, antimony, and bismuth; selenides of cadmium and lead; and telluride of cadmium. Other examples of the compound semiconductor include: phosphides of zinc, gallium, indium, and cadmium; gallium arsenide; copper-indium-selenide; and copper-indium-sulfide.

Among them, oxide semiconductors are preferable. Particularly, titanium oxide, zinc oxide, tin oxide, and niobium oxide are more preferable.

These may be used alone or in combination. Moreover, a crystal type of the semiconductor material is not particularly limited and may be appropriately selected depending on the intended purpose. The crystal type thereof may be a single crystal, polycrystalline, or amorphous.

A film thickness of the compact layer is not particularly limited and may be appropriately selected depending on the intended purpose. The film thickness thereof is preferably 10 nm or more but 1 micrometer or less, more preferably 20 nm or more but 700 nm or less.

A method for producing the compact layer is not particularly limited and may be appropriately selected depending on the intended purpose. Examples thereof include a method for forming a thin film under vacuum (vacuum film formation method) and a wet film formation method.

Examples of the vacuum film formation method include a sputtering method, a pulse laser deposition method (PLD method), an ion beam sputtering method, an ion assisted deposition method, an ion plating method, a vacuum deposition method, an atomic layer deposition method (ALD method), and a chemical vapor deposition method (CVD method).

Examples of the wet film formation method include a sol-gel method. The sol-gel method is the following method. Specifically, a solution is allowed to undergo a chemical reaction such as hydrolysis or polymerization·condensation to prepare gel. Then, it is subjected to a heat treatment to facilitate compactness. When the sol-gel method is used, a method for coating the sol solution is not particularly limited and may be appropriately selected depending on the intended purpose. Examples thereof include a dip method, a spraying method, a wire bar method, a spin coating method, a roller coating method, a blade coating method, a gravure coating method, and wet printing methods such as relief printing, offset printing, gravure printing, intaglio printing, rubber plate printing, and screen printing. A temperature at which the heat treatment is performed after the sol solution is coated is preferably 80 degrees Celsius or more, more preferably 100 degrees Celsius or more.

<<<Porous Layer>>>

The porous layer is not particularly limited and may be appropriately selected depending on the intended purpose, so long as it is a layer that includes an electron transport material and is less compact (i.e., porous) than the compact layer. Note that, being less compact means that a packing density of the porous layer is lower than a packing density of the compact layer.

The electron transport material is not particularly limited and may be appropriately selected depending on the intended purpose, but is preferably a semiconductor material similarly to the case of the compact layer. As the semiconductor material, those similar to the materials used in the compact layer can be used.

In addition, the electron transport material constituting the porous layer has a form of particles, and these particles are preferably joined to form a porous film.

A number average particle diameter of primary particles of the electron transport material is not particularly limited and may be appropriately selected depending on the intended purpose. The number average particle diameter thereof is preferably 1 nm or more but 100 nm or less, more preferably 10 nm or more but 50 nm or less. Moreover, a semiconductor material having a lager particle size than the number average particle diameter may be mixed or laminated. Use of such a semiconductor material may improve a conversion efficiency because of an effect of scattering incident light. In this case, the number average particle diameter is preferably 50 nm or more but 500 nm or less.

As the electron transport material in the porous layer, titanium oxide particles can be suitably used. When the electron transport material in the porous layer is titanium oxide particles, the conduction band is high, which makes it possible to obtain a high open-circuit voltage. When the electron transport material in the porous layer is the titanium oxide particles, the refractive index is high, and a high short circuit current can be obtained because of an effect of confining light. Moreover, when the electron transport material in the porous layer is the titanium oxide particles, it is advantageous because the permittivity of the porous layer becomes high and the mobility of the electrons becomes high to obtain a high fill factor (shape factor). That is, the electron transport layer preferably includes the porous layer including titanium oxide particles because the open-circuit voltage and the fill factor can be improved.

An average thickness of the porous layer is not particularly limited and may be appropriately selected depending on the intended purpose. The average thickness thereof is preferably 30 nm or more but 1 micrometer or less, more preferably 100 nm or more but 600 nm or less.

Moreover, the porous layer may include a multilayer structure. The porous layer having a multilayer structure can be produced by coating a dispersion liquid of particles of the electron transport material different in a particle diameter several times, or by coating a dispersion liquid of the electron transport material, a resin, and an additive different in formulation several times. It is effective to coat the dispersion liquid of particles of the electron transport material several times when an average thickness (film thickness) of the porous layer is adjusted.

A method for producing the porous layer is not particularly limited and may be appropriately selected depending on the intended purpose. Examples thereof include an immersion method, a spin coating method, a spraying method, a dip method, a roller method, and an air knife method. As the method for producing the porous layer, a method by causing precipitation using a supercritical fluid such as carbon dioxide can be used.

A method for producing the particles of the electron transport material is, for example, a mechanically pulverizing method using a known milling apparatus. Through this method, it is possible to prepare a dispersion liquid of the semiconductor material by dispersing, in water or a solvent, an electron transport material in the form of particles alone or a mixture of the semiconductor material and a resin.

Examples of the resin include polymers or copolymers of vinyl compounds (e.g., styrene, vinyl acetate, acrylic acid ester, and methacrylic acid ester), silicone resins, phenoxy resins, polysulfone resins, polyvinyl butyral resins, polyvinyl formal resins, polyester resins, cellulose ester resins, cellulose ether resins, urethane resins, phenol resins, epoxy resins, polycarbonate resins, polyarylate resins, polyamide resins, and polyimide resins. These may be used alone or in combination.

Examples of the solvent include water, alcohol solvents, ketone solvents, ester solvents, ether solvents, amide solvents, halogenated hydrocarbon solvents, and hydrocarbon solvents.

Examples of the alcohol solvent include methanol, ethanol, isopropyl alcohol, and α-terpineol.

Examples of the ketone solvent include acetone, methyl ethyl ketone, and methyl isobutyl ketone.

Examples of the ester solvent include ethyl formate, ethyl acetate, and n-butyl acetate.

Examples of the ether solvent include diethyl ether, dimethoxy ethane, tetrahydrofuran, dioxolane, and dioxane.

Examples of the amide solvent include N,N-dimethylformamide, N,N-dimethylacetoamide, and N-methyl-2-pyrrolidone.

Examples of the halogenated hydrocarbon solvent include dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvent include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

These may be used alone or in combination.

To the dispersion liquid including the electron transport material or the paste including the electron transport material obtained through the sol-gel method etc., acid, a surfactant, or a chelating agent may be added in order to prevent reaggregation of the particles.

Examples of the acid include hydrochloric acid, nitric acid, and acetic acid.

Examples of the surfactant include polyoxyethylene octylphenyl ether.

Examples of the chelating agent include acetyl acetone, 2-aminoethanol, and ethylene diamine.

Moreover, addition of a thickener is also an effective means for the purpose of improving film forming ability.

Examples of the thickener include polyethylene glycol, polyvinyl alcohol, and ethyl cellulose.

After the electron transport material is coated, it is possible to electronically contact particles of the electron transport material with each other and to perform baking, irradiation of microwave or electron beams, or irradiation of laser light in order to improve strength of the film and close adhesiveness to the substrate. These treatments may be performed alone or two or more treatments may be performed in combination.

When the porous layer formed of the electron transport material is baked, a baking temperature is not particularly limited and may be appropriately selected depending on the intended purpose. However, the baking temperature thereof is preferably 30 degrees Celsius or more but 700 degrees Celsius or less, more preferably 100 degrees Celsius or more but 600 degrees Celsius or less. When the baking temperature thereof is 30 degrees Celsius or more but 700 degrees Celsius or less, the porous layer can be baked while the first substrate is prevented from being increased in a resistance value and being melted. The baking time is not particularly limited and may be appropriately selected depending on the intended purpose, but is preferably 10 minutes or more but 10 hours or less.

When the porous layer formed of the electron transport material is irradiated with microwave, the irradiation time is not particularly limited and may be appropriately selected depending on the intended purpose, but is preferably 1 hour or less. In this case, light may be emitted from a surface side on which the porous layer is formed, and light may be emitted from a surface side on which the porous layer is not formed.

After the porous layer formed of the electron transport material is baked, a chemical plating treatment using a mixed solution of an aqueous titanium tetrachloride solution or an organic solvent or an electrochemical plating treatment using an aqueous titanium trichloride solution may be performed for the purpose of increasing a surface area of the porous layer.

In this way, the film obtained by, for example, baking the electron transport material having a diameter of several tens of nanometers has a porous structure having many voids. The porous structure has a considerably high surface area and the surface area can be represented by a roughness factor. The roughness factor is a numerical value presenting an actual area of the inside of the porous bodies relative to an area of particles of the electron transport material coated on the first substrate or the compact layer. Therefore, a larger roughness factor is preferable, but the roughness factor is preferably 20 or more in terms of relationship between the roughness factor and an average thickness of the electron transport layer.

The particles of the electron transport material may be doped with a lithium compound. A specific method thereof is a method by depositing a solution of a lithium bis(trifluoromethanesulfonimide) compound on the particles of the electron transport material through, for example, spin coating and then subjecting it to a baking treatment.

The lithium compound is not particularly limited and may be appropriately selected depending on the intended purpose. Examples thereof include lithium bis(trifluoromethanesulfonimide), lithium perchlorate, and lithium iodide.

<<Perovskite Layer>>

The perovskite layer means a layer that includes a perovskite compound and absorbs light to sensitize the electron transport layer. Therefore, the perovskite layer is preferably disposed next to the electron transport layer.

A shape and a size of the perovskite layer are not particularly limited and may be appropriately selected depending on the intended purpose, so long as the perovskite layers within at least two photoelectric conversion elements adjacent to each other are separated by a hole transport layer that will be described hereinafter.

The perovskite compound is a composite substance of an organic compound and an inorganic compound, and is represented by the following General Formula (1).

XαYβMγ General Formula (1)

In the above General Formula (1), a ratio of α:β:γ is 3:1:1, and β and γ represent an integer of more than 1. For example, X can be a halogen ion, Y can be an ion of an alkyl amine compound, and M can be a metal ion.

X in the above General Formula (1) is not particularly limited and may be appropriately selected depending on the intended purpose. Examples thereof include halogen ions such as chlorine, bromine, and iodine. These may be used alone or in combination.

Y in the above General Formula (1) is, for example, an ion of an alkyl amine compound (e.g., methylamine, ethylamine, n-butylamine, and formamidine), cesium, potassium, and rubidium. In the case of the perovskite compound of lead halide and methylammonium, a peak λmax of the optical absorption spectrum is about 350 nm when the halogen ion is Cl, the peak λmax is about 410 nm when the halogen ion is Br, and the peak λmax is about 540 nm when the halogen ion is I. As described above, the peak λmax is shifted to a longer wavelength side, so a usable spectrum width (band width) varies.

M in the above General Formula (1) is not particularly limited and may be appropriately selected depending on the intended purpose. Examples thereof include metals such as lead, indium, antimony, tin, copper, and bismuth.

The perovskite layer preferably has a laminated perovskite structure where a layer formed of metal halide and a layer formed of arranged organic cationic molecules are alternately laminated.

A method for forming the perovskite layer is not particularly limited and may be appropriately selected depending on the intended purpose. Examples of the method include a method by coating a solution that dissolves or disperses metal halide and halogenated alkylamine, followed by drying.

Moreover, examples of the method for forming the perovskite layer include a twostep precipitation method as described below. Specifically, a solution that dissolves or disperses metal halide is coated and then is dried. Then, the resultant is immersed in a solution that dissolves halogenated alkylamine to form the perovskite compound.

Moreover, examples of the method for forming the perovskite layer include a method for precipitating crystals by adding a poor solvent (solvent having a small solubility) for the perovskite compound while the solution that dissolves or disperses metal halide and halogenated alkylamine being coated.

In addition, examples of the method for forming the perovskite layer include a method for depositing metal halide in a gas filled with, for example, methylamine.

Among them, preferable is the method for precipitating crystals by adding a poor solvent for the perovskite compound while the solution that dissolves or disperses metal halide and halogenated alkylamine being coated.

A method for coating the solution is not particularly limited and may be appropriately selected depending on the intended purpose. Examples thereof include an immersion method, a spin coating method, a spraying method, a dip method, a roller method, and an air knife method. As the method for coating the solution, a method for performing precipitation in a supercritical fluid using, for example, carbon dioxide may be used.

Moreover, the perovskite layer preferably includes a sensitizing dye.

A method for forming the perovskite layer including the sensitizing dye is not particularly limited and may be appropriately selected depending on the intended purpose. Examples thereof include a method by mixing the perovskite compound and the sensitizing dye and a method by forming the perovskite layer and then adsorbing the sensitizing dye.

The sensitizing dye is not particularly limited and may be appropriately selected depending on the intended purpose, so long as it is a compound photoexcited by excitation light to be used.

Examples of the sensitizing dye include: metal-complex compounds described in, for example, Japanese Translation of PCT International Application Publication No. JP-T-07-500630, Japanese Unexamined Patent Application Publication No. 10-233238, Japanese Unexamined Patent Application Publication No. 2000-26487, Japanese Unexamined Patent Application Publication No. 2000-323191, and Japanese Unexamined Patent Application Publication No. 2001-59062; coumarin compounds described in, for example, Japanese Unexamined Patent Application Publication No. 10-93118, Japanese Unexamined Patent Application Publication No. 2002-164089, Japanese Unexamined Patent Application Publication No. 2004-95450, and J. Phys. Chem. C, 7224, Vol. 111 (2007); polyene compounds described in, for example, Japanese Unexamined Patent Application Publication No. 2004-95450, and Chem. Commun., 4887 (2007); indoline compounds described in, for example, Japanese Unexamined Patent Application Publication No. 2003-264010, Japanese Unexamined Patent Application Publication No. 2004-63274, Japanese Unexamined Patent Application Publication No. 2004-115636, Japanese Unexamined Patent Application Publication No. 2004-200068, Japanese Unexamined Patent Application Publication No. 2004-235052, J. Am. Chem. Soc., 12218, Vol. 126 (2004), Chem. Commun., 3036 (2003), and Angew. Chem. Int. Ed., 1923, Vol. 47 (2008); thiophene compounds described in, for example, J. Am. Chem. Soc., 16701, Vol. 128 (2006), and J. Am. Chem. Soc., 14256, Vol. 128 (2006); cyanine dyes described in, for example, Japanese Unexamined Patent Application Publication No. 11-86916, Japanese Unexamined Patent Application Publication No. 11-214730, Japanese Unexamined Patent Application Publication No. 2000-106224, Japanese Unexamined Patent Application Publication No. 2001-76773, and Japanese Unexamined Patent Application Publication No. 2003-7359; merocyanine dyes described in, for example, Japanese Unexamined Patent Application Publication No. 11-214731, Japanese Unexamined Patent Application Publication No. 11-238905, Japanese Unexamined Patent Application Publication No. 2001-52766, Japanese Unexamined Patent Application Publication No. 2001-76775, and Japanese Unexamined Patent Application Publication No. 2003-7360; 9-aryl xanthene compounds described in, for example, Japanese Unexamined Patent Application Publication No. 10-92477, Japanese Unexamined Patent Application Publication No. 11-273754, Japanese Unexamined Patent Application Publication No. 11-273755, and Japanese Unexamined Patent Application Publication No. 2003-31273; triarylmethane compounds described in, for example, Japanese Unexamined Patent Application Publication No. 10-93118, and Japanese Unexamined Patent Application Publication No. 2003-31273; and phthalocyanine compounds and porphyrin compounds described in, for example, Japanese Unexamined Patent Application Publication No. 09-199744, Japanese Unexamined Patent Application Publication No. 10-233238, Japanese Unexamined Patent Application Publication No. 11-204821, Japanese Unexamined Patent Application Publication No. 11-265738, J. Phys. Chem., 2342, Vol. 91 (1987), J. Phys. Chem. B, 6272, Vol. 97 (1993), Electroanal. Chem., 31, Vol. 537 (2002), Japanese Unexamined Patent Application Publication No. 2006-032260, J. Porphyrins Phthalocyanines, 230, Vol. 3 (1999), Angew. Chem. Int. Ed., 373, Vol. 46 (2007), and Langmuir, 5436, Vol. 24 (2008). Among them, metal-complex compounds, indoline compounds, thiophene compounds, and porphyrin compounds are preferable.

<<Hole Transport Layer>>

The hole transport layer means a layer that transports holes generated in the perovskite layer to a second electrode that will be described hereinafter. Therefore, the hole transport layer is preferably disposed next to the perovskite layer.

A shape and a size of the hole transport layer is not particularly limited and may be appropriately selected depending on the intended purpose, so long as the hole transport layers are continuous with each other and the hole transport layer can separate the first electrodes, the electron transport layers, and the perovskite layers within at least two photoelectric conversion elements adjacent to each other.

By separating the first electrodes, the electron transport layers, and the perovskite layers by the hole transport layers that are continuous with each other within the at least two photoelectric conversion elements adjacent to each other, the porous titanium oxide layers (electron transport layer) are separated, and less recombination of electrons through diffusion is caused, which makes it possible to maintain power generation efficiency even after exposure to light having a high illuminance for a long period of time.

The hole transport layer includes a solid hole transport material, and further includes other materials if necessary.

The solid hole transport material (hereinafter may be simply referred to as “hole transport material”) is not particularly limited and may be appropriately selected depending on the intended purpose, so long as it is a material that can have a property of transporting holes. The solid hole transport material may be, for example, an inorganic compound or an organic compound, but it is preferably an organic compound.

When an organic compound is used as the hole transport material, the hole transport layer may have a structure formed of a single compound or may have a structure formed of a plurality kinds of compounds, but a structure formed of a plurality kinds of compounds is preferable. That is, the hole transport layer preferably includes a plurality kinds of compounds.

When the hole transport layer includes a plurality kinds of compounds, the hole transport layer, which is closer to the second electrode, preferably includes the polymer material. By using the polymer material in the hole transport layer that is closer to the second electrode, it is possible to make a surface of the perovskite layer smooth, and thus photoelectric conversion characteristics can be improved. Moreover, the polymer material is excellent in an ability to cover the surface of the porous layer, because the polymer material hardly permeate through the inside of the porous layer. Therefore, an effect of preventing short circuit when electrodes are provided may be obtained in some cases.

The hole transport material in the case where the hole transport layer is formed of a single compound is not particularly limited and may be appropriately selected depending on the intended purpose. Examples thereof include: oxadiazole compounds described in, for example, Japanese Examined Patent Publication No. 34-5466; triphenylmethane compounds described in, for example, Japanese Examined Patent Publication No. 45-555; pyrazoline compounds described in, for example, Japanese Examined Patent Publication No. 52-4188; hydrazone compounds described in, for example, Japanese Examined Patent Publication No. 55-42380; oxadiazole compounds described in, for example, Japanese Unexamined Patent Application Publication No. 56-123544; tetraaryl benzidine compounds described in, for example, Japanese Unexamined Patent Application Publication No. 54-58445; and stilbene compounds described in, for example, Japanese Unexamined Patent Application Publication No. 58-65440 or Japanese Unexamined Patent Application Publication No. 60-98437.

The polymer material, which is used in the hole transport layer that is closer to the second electrode in the case where the hole transport layer includes a plurality kinds of compounds, is not particularly limited and may be appropriately selected depending on the intended purpose. Examples thereof include: polythiophene compounds such as poly(3-n-hexylthiophene), poly(3-n-octyloxythiophene), poly(9,9′-dioctyl-fluorene-co-bithiophene), poly(3,3′″-didodecyl-quarter thiophene), poly(3,6-dioctylthieno[3,2-b]thiophene), poly(2,5-bis(3-decylthiophene-2-yl)thieno[3,2-b]thiophene), poly(3,4-didecylthiophene-co-thieno[3,2-b]thiophene), poly(3,6-dioctylthieno[3,2-b]thiophene-co-thieno[3,2-b]thiophene), poly(3,6-dioctylthieno[3,2-b]thiophene-co-thiophene), and poly(3,6-dioctylthieno[3,2-b]thiophene-co-bithiophene); polyphenylene vinylene compounds such as poly[2-methoxy-5-(2-ethylhexyloxy)-1,4-phenylenevinylene], poly[2-methoxy-5-(3,7-dimethyloctyloxy)-1,4-phenylenevinylene], and poly[(2-methoxy-5-(2-ethylhexyloxy)-1,4-phenylenevinylene)-co-(4,4′-biphenylene-vinylene)]; polyfluorene compounds such as poly(9,9′-didodecylfluorenyl-2,7-diyl), poly[(9,9-dioctyl-2,7-divinylenefluorene)-alt-co-(9,10-anthracene)], poly[(9,9-dioctyl-2,7-divinylenefluorene)-alt-co-(4,4′-biphenylene)], poly[(9,9-dioctyl-2,7-divinylenefluorene)-alt-co-(2-methoxy-5-(2-ethylhexyloxy)-1,4-phenylene)], and poly[(9,9-dioctyl-2,7-diyl)-co-(1,4-(2,5-dihexyloxy)benzene)]; polyphenylene compounds such as poly[2,5-dioctyloxy-1,4-phenylene], and poly[2,5-di(2-ethylhexyloxy-1,4-phenylene]; polyarylamine compounds such as poly[(9,9-dioctylfluorenyl-2,7-diyl)-alt-co-(N,N′-diphenyl)-N,N′-di(p-hexylphenyl)-1, 4-diaminobenzene], poly[(9,9-dioctylfluorenyl-2,7-diyl)-alt-co-(N,N′-bis(4-octyloxyphenyl)benzidine-N,N′-(1,4-diphenylene)], poly [(N,N′-bis(4-octyloxyphenyl)benzidine-N,N′-(1,4-diphenylene)], poly [(N,N′-bis(4-(2-ethylhexyloxy)phenyl)benzidine-N,N′-(1,4-diphenylene)], poly[phenylimino-1,4-phenylenevinylene-2,5-dioctyloxy-1,4-phenylenevinylene-1,4-phenylene], poly[p-tolylimino-1,4-phenylenevinylene-2,5-di(2-ethylhexyloxy)-1,4-phenylenevinylene-1,4-phenylene], and poly[4-(2-ethylhexyloxy)phenylimino-1,4-biphenylene]; and polythiadiazole compounds such as poly[(9,9-dioctylfluorenyl-2,7-diyl)-alt-co-(1,4-benzo(2,1′,3)thiadiazole], and poly(3,4-didecylthiophene-co-(1,4-benzo(2,1′,3)thiadiazole). Among them, polythiophene compounds, polyarylamine compounds, and spirobifluorene compounds as described in, for example, Japanese Unexamined Patent Application Publication No. 2007-115665, Japanese Unexamined Patent Application Publication No. 2014-72327, Japanese Unexamined Patent Application Publication No. 2000-067544, JP, WO2004/063283, WO2011/030450, WO2011/45321, WO2013/042699, and WO2013/121835 are preferable, spirobifluorene compounds are more preferable, in terms of carrier mobility and ionization potential.

Other materials included in the hole transport layer are not particularly limited and may be appropriately selected depending on the intended purpose. Examples thereof include additives and oxidizing agents.

The additive is not particularly limited and may be appropriately selected depending on the intended purpose. Examples thereof include: metal iodides such as iodine, lithium iodide, sodium iodide, potassium iodide, cesium iodide, calcium iodide, copper iodide, iron iodide, and silver iodide; quaternary ammonium salts such as tetraalkylammonium iodide and pyridinium iodide; metal bromides such as lithium bromide, sodium bromide, potassium bromide, cesium bromide, and calcium bromide; bromine salts of quaternary ammonium compounds such as tetraalkylammonium bromide and pyridinium bromide; metal chlorides such as copper chloride and silver chloride; metal acetates such as copper acetate, silver acetate, and palladium acetate; metal sulfates such as copper sulfate and zinc sulfate; metal complexes such as ferrocyanate-ferricyanate and ferrocene-ferricinium ion; sulfur compounds such as sodium polysulfide and alkylthiol-alkyl disulfide; viologen dyes; hydroquinones; ionic liquids described in, for example, Inorg. Chem. 35 (1996) 1168, such as 1,2-dimethyl-3-n-propylimidazolinium iodide, 1-methyl-3-n-hexylimidazolinium iodide, 1,2-dimethyl-3-ethyl imidazolium trifluoromethane sulfonate, 1-methyl-3-butylimidazolium nonafluorobutyl sulfonate, and 1-methyl-3-ethyl imidazolium bis(trifluoromethyl)sulfonyl imide; basic compounds such as pyridine, 4-t-butylpyridine, and benzimidazole; and lithium compounds such as lithium trifluoromethanesulfonylimide and lithium diisopropylimide.

The oxidizing agent is not particularly limited and may be appropriately selected depending on the intended purpose. Examples thereof include tris (4-bromophenyl) aminium hexachloroantimonate, silver hexafluoroantimonate, nitrosonium tetrafluoroborate, silver nitrate, and cobalt complex. Note that, it is not necessary to oxidize the entire hole transport material with the oxidizing agent, and it is effective so long as the hole transport material is partially oxidized. After the reaction, the oxidizing agent may be removed or may not be removed outside the system.

Inclusion of the oxidizing agent in the hole transport layer can partially or entirely form the hole transport material into radical cations, which makes it possible to improve conductivity and to increase safety and durability of output characteristics.

An average thickness of the hole transport layer is not particularly limited and may be appropriately selected depending on the intended purpose. However, the average thickness thereof is preferably 0.01 micrometers or more but 20 micrometers or less, more preferably 0.1 micrometers or more but 10 micrometers or less, still more preferably 0.2 micrometers or more but 2 micrometers or less, on the perovskite layer.

The hole transport layer can be directly formed on the perovskite layer. A method for producing the hole transport layer is not particularly limited and may be appropriately selected depending on the intended purpose. Examples of the method include a method where a thin film is formed in vacuum through vacuum deposition and a wet film forming method. In particular, among them, a wet film forming method is preferable, a method by coating the hole transport layer on the perovskite layer is more preferable, in terms of production cost.

The wet film forming method is not particularly limited and may be appropriately selected depending on the intended purpose. Examples thereof include a dip method, a spraying method, a wire bar method, a spin coating method, a roller coating method, a blade coating method, and a gravure coating method. As the wet printing method, methods such as relief printing, offset printing, gravure printing, intaglio printing, rubber plate printing, and screen printing may be used.

Moreover, the hole transport layer may be produced by forming a film in a supercritical fluid or subcritical fluid having a lower temperature and pressure than a critical point. The supercritical fluid means a fluid, which exists as a non-condensable high-density fluid in a temperature and pressure region exceeding the limit (critical point) at which a gas and a liquid can coexist and does not condense even when being compressed, and is a fluid in a state of being equal to or higher than the critical temperature and is equal to or higher than the critical pressure. The supercritical fluid is not particularly limited and may be appropriately selected depending on the intended purpose, but is preferably a supercritical fluid having a low critical temperature.

The subcritical fluid is not particularly limited and may be appropriately selected depending on the intended purpose, so long as it is a fluid that exists as a high-pressure liquid in a temperature and pressure region near the critical point. The fluids as exemplified as the supercritical fluid can be suitably used as the subcritical fluid.

Examples of the supercritical fluid include carbon monoxide, carbon dioxide, ammonia, nitrogen, water, alcohol solvents, hydrocarbon solvents, halogen solvents, and ether solvents.

Examples of the alcohol solvent include methanol, ethanol, and n-butanol.

Examples of the hydrocarbon solvent include ethane, propane, 2,3-dimethylbutane, benzene, and toluene. Examples of the halogen solvent include methylene chloride and chlorotrifluoromethane.

Examples of the ether solvent include dimethyl ether.

These may be used alone or in combination.

Among them, carbon dioxide, which has a critical pressure of 7.3 MPa and a critical temperature of 31 degrees Celsius, is preferable because carbon dioxide easily generates a supercritical state, and it is incombustible and is easily handled.

A critical temperature and a critical pressure of the supercritical fluid are not particularly limited and may be appropriately selected depending on the intended purpose. The critical temperature of the supercritical fluid is preferably −273 degrees Celsius or more but 300 degrees Celsius or less, more preferably 0 degrees Celsius or more but 200 degrees Celsius or less.

In addition to the supercritical fluid and subcritical fluid, an organic solvent or an entrainer may be used in combination. Adjustment of solubility in the supercritical fluid can be easily performed by adding the organic solvent or the entrainer.

The organic solvent is not particularly limited and may be appropriately selected depending on the intended purpose. Examples of the organic solvent include ketone solvents, ester solvents, ether solvents, amide solvents, halogenated hydrocarbon solvents, and hydrocarbon solvents.

Examples of the ketone solvent include acetone, methyl ethyl ketone, and methyl isobutyl ketone.

Examples of the ester solvent include ethyl formate, ethyl acetate, and n-butyl acetate.

Examples of the ether solvent include diisopropyl ether, dimethoxy ethane, tetrahydrofuran, dioxolane, and dioxane.

Examples of the amide solvent include N,N-dimethylformamide, N,N-dimethylacetoamide, and N-methyl-2-pyrrolidone.

Examples of the halogenated hydrocarbon solvent include dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvent include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

These may be used alone or in combination.

After the hole transport material is laminated on the perovskite layer, a press processing step may be performed. By performing the press processing, the hole transport material is closely adhered to the perovskite layer, which may improve the power generation efficiency in some cases.

A method of the press processing is not particularly limited and may be appropriately selected depending on the intended purpose. Examples thereof include the press molding method using a plate, which is represented by the infrared spectroscopy (IR) tablet molding device and the roll press method using a roller.

A pressure at which the press processing is performed is preferably 10 kgf/cm² or more, more preferably 30 kgf/cm² or more.

The time of the pressing is not particularly limited and may be appropriately selected depending on the intended purpose. The time thereof is preferably 1 hour or less. Moreover, heat may be applied at the time of the pressing.

At the time of the pressing, a release agent may be disposed between a pressing machine and the electrode.

The release agent is not particularly limited and may be appropriately selected depending on the intended purpose. Examples thereof include fluororesins, such as polyethylene tetrafluoride, polychloro ethylene trifluoride, ethylene tetrafluoride-propylene hexafluoride copolymers, perfluoroalkoxy fluoride resins, polyvinylidene fluoride, ethylene-ethylene tetrafluoride copolymers, ethylene-chloroethylene trifluoride copolymers, and polyvinyl fluoride. These may be used alone or in combination.

After performing the pressing but before disposing a second electrode, a film including metal oxide may be disposed between the hole transport layer and the second electrode.

The metal oxide is not particularly limited and may be appropriately selected depending on the intended purpose. Examples of thereof include molybdenum oxide, tungsten oxide, vanadium oxide, and nickel oxide. These may be used alone or in combination. Among them, molybdenum oxide is preferable.

A method for disposing the film including metal oxide on the hole transport layer is not particularly limited and may be appropriately selected depending on the intended purpose. Examples of the method include a method where a thin film is formed in vacuum such as sputtering and vacuum vapor deposition, and a wet film forming method.

The wet film forming method in the case where the film including metal oxide is formed is preferably a method by preparing a paste in which powders or sol of the metal oxide is dispersed and coating it on the hole transport layer.

The wet film forming method is not particularly limited and may be appropriately selected depending on the intended purpose. Examples thereof include a dip method, a spraying method, a wire bar method, a spin coating method, a roller coating method, a blade coating method, and a gravure coating method. As the wet printing method, methods such as relief printing, offset printing, gravure printing, intaglio printing, rubber plate printing, and screen printing may be used.

An average thickness of the film including metal oxide is not particularly limited and may be appropriately selected depending on the intended purpose. However, the average thickness thereof is preferably 0.1 nm or more but 50 nm or less, more preferably 1 nm or more but 10 nm or less.

<<Second Electrode>>

The second electrode is preferably formed on the hole transport layer or a film of the metal oxide in the hole transport layer. The second electrode can use the same as the first electrode.

A shape, a structure, and a size of the second electrode are not particularly limited and may be appropriately selected depending on the intended purpose.

Examples of a material of the second electrode include metals, carbon compounds, conductive metal oxides, and conductive polymers.

Examples of the metal include platinum, gold, silver, copper, and aluminum.

Examples of the carbon compound include graphite, fullerene, carbon nanotube, and graphene.

Examples of the conductive metal oxide include ITO, FTO, and ATO.

Examples of the conductive polymer include polythiophene and polyaniline.

These may be used alone or in combination.

The second electrode can be appropriately formed on the hole transport layer through a method such as coating, laminating, deposition, CVD, or bonding, depending on a kind of the material to be used or a kind of the hole transport layer.

Within the photoelectric conversion element, at least one of the first electrode and the second electrode is preferably substantially transparent. When the solar cell module of the present disclosure is used, the first electrode is preferably transparent to allow entrance of incident light from a side of the first electrode. In this case, a material that reflects light is preferably used for the second electrode, and glass, plastic, and a metal thin film on which a metal or conductive oxide is deposited are preferably used. In addition, provision of an anti-reflection layer at a side of the electrode into which the incident light enters is an effective means.

<Second Substrate>

The second substrate is disposed so as to face the first substrate, so that the first substrate and the second substrate sandwich the photoelectric conversion elements.

A shape, a structure, and a size of the substrate is not particularly limited and may be appropriately selected depending on the intended purpose.

A material of the second substrate is not particularly limited and may be appropriately selected depending on the intended purpose. Examples thereof include glass, plastic films, and ceramics.

A convex-concave part may be formed at a connection part of the second substrate with a sealing member, which will be described hereinafter, in order to increase close adhesiveness.

A formation method of the convex-concave part is not particularly limited and may be appropriately selected depending on the intended purpose. Examples of the formation method include a sand blasting method, a water blasting method, a chemical etching method, a laser processing method, and a method using abrasive paper.

A method for increasing close adhesiveness between the second substrate and the sealing member may be, for example, a method by removing an organic matter on the surface of the second substrate, or a method for improving hydrophilicity of the second substrate. The method for removing an organic matter on the surface of the second substrate is not particularly limited and may be appropriately selected depending on the intended purpose. Examples of the method include UV ozone washing and an oxygen plasma treatment.

<Sealing Member>

The sealing member is disposed between the first substrate and the second substrate, and seals the photoelectric conversion elements.

A material of the sealing member is not particularly limited and may be appropriately selected depending on the intended purpose. Examples thereof include cured products of acrylic resins and cured products of epoxy resins.

As the cured product of the acrylic resin, any of materials known in the art can be used, so long as the cured product of the acrylic resin is a product obtained by curing a monomer or oligomer including an acryl group in a molecule thereof.

As the cured product of the epoxy resin, any of materials known in the art can be used, so long as the cured product of the epoxy resin is a product obtained by curing a monomer or oligomer including an epoxy group in a molecule thereof.

Examples of the epoxy resin include water-dispersing epoxy resins, non-solvent epoxy resins, solid epoxy resins, heat-curable epoxy resins, curing agent-mixed epoxy resins, and ultraviolet ray-curable epoxy resins. Among them, heat-curable epoxy resins and ultraviolet ray-curable epoxy resins are preferable, ultraviolet ray-curable epoxy resins are more preferable. Note that, heating may be performed even when an ultraviolet ray-curable epoxy resin is used, and heating is preferably performed even after curing through ultraviolet ray irradiation.

Examples of the epoxy resin include bisphenol A-based epoxy resins, bisphenol F-based epoxy resins, novolac-based epoxy resins, alicyclic epoxy resins, long-chain aliphatic epoxy resins, glycidyl amine-based epoxy resins, glycidyl ether-based epoxy resins, and glycidyl ester-based epoxy resins. These may be used alone or in combination.

A curing agent or various additives are preferably mixed with the epoxy resin if necessary.

The curing agent is not particularly limited and may be appropriately selected depending on the intended purpose. The curing agents are classified into, for example, amine-based curing agents, acid anhydride-based curing agents, polyamide-based curing agents, and other curing agents.

Examples of the amine-based curing agent include: aliphatic polyamine such as diethylenetriamine and triethylenetetramine; and aromatic polyamine such as methphenylenediamine, diaminodiphenylmethane, and diaminodiphenylsulfone.

Examples of the acid anhydride-based curing agent include phthalic anhydride, tetrahydrophthalic anhydride, hexahydrophthalic anhydride, methyltetrahydrophthalic anhydride, methylnadic anhydride, pyromellitic anhydride, HET anhydride, and dodecenylsuccinic anhydride.

Examples of other curing agents include imidazoles and polymercaptan. These may be used alone or in combination.

The additive is not particularly limited and may be appropriately selected depending on the intended purpose. Examples thereof include fillers, gap agents, polymerization initiators, drying agents (moisture absorbents), curing accelerators, coupling agents, flexibilizers, colorants, flame retardant auxiliaries, antioxidants, and organic solvents. Among them, fillers, gap agents, curing accelerators, polymerization initiators, and drying agents (moisture absorbents) are preferable, fillers and polymerization initiators are more preferable.

Inclusion of the filler as the additive prevents entry of moisture or oxygen, and further can achieve effects such as reduction in volumetric shrinkage at the time of curing, reduction in an amount of outgas at the time of curing or heating, improvement of mechanical strength, and control of thermal conductivity or fluidity. Therefore, inclusion of the filler as the additive is considerably effective in maintaining stable output under various environments.

In addition, regarding output properties or durability of a photoelectric conversion element, not only influence of entering moisture or oxygen, but also influence of outgas generated at the time of curing or heating the sealing member cannot be ignored. Especially, outgas generated at the time of heating greatly affects output properties of the photoelectric conversion element stored in a high temperature environment.

Entry of moisture or oxygen can be prevented by adding filler, a gap agent, or a drying agent into the sealing member, and therefore an amount of the sealing member to be used can be reduced to thereby obtain an effect of reducing outgas. Inclusion of the filler, the gap agent, or the drying agent in the sealing member is effective not only at the time of curing but also at the time when the photoelectric conversion element is stored under a high temperature environment.

The filler is not particularly limited and may be appropriately selected depending on the intended purpose. Examples thereof include inorganic fillers such as crystalline or amorphous silica, talc, alumina, aluminum nitride, silicon nitride, calcium silicate, and calcium carbonate. These may be used alone or in combination.

An average primary particle diameter of the filler is preferably 0.1 micrometers or more but 10 micrometers or less, more preferably 1 micrometer or more but 5 micrometers or less. When the average primary particle diameter of the filler falls within the above preferable range, an effect of preventing entry of moisture or oxygen can be sufficiently obtained, an appropriate viscosity is obtained, and close adhesiveness to a substrate or a defoaming property is improved. In addition, it is also effective in terms of control of a width of the sealing part or workability.

An amount of the filler is preferably 10 parts by mass or more but 90 parts by mass or less, more preferably 20 parts by mass or more but 70 parts by mass or less, relative to the entire sealing member (100 parts by mass). When the amount of the filler falls within the above preferable range, an effect of preventing entry of moisture or oxygen can be sufficiently obtained, an appropriate viscosity is obtained, and close adhesiveness and workability is good.

The gap agent is also called a gap controlling agent or a spacer agent. By including the gap agent as the additive, it is possible to control the gap of the sealing part. For example, when a sealing member is provided on a first substrate or a first electrode and a second substrate is provided thereon for sealing, a gap of the sealing part is matched with a size of the gap agent because the sealing member includes the gap agent. As a result, it is possible to easily control the gap of the sealing part.

The gap agent is not particularly limited and may be appropriately selected depending on the intended purpose, so long as it is particulate, has a uniform diameter, and has high solvent resistance and heat resistance. The gap agent is preferably a material which has high affinity to an epoxy resin and is in the form of sphere particles. Specific examples thereof include glass beads, silica fine particles, and organic resin fine particles. These may be used alone or in combination.

A particle diameter of the gap agent can be selected depending on a gap of the sealing part to be set. The particle diameter thereof is preferably 1 micrometer or more but 100 micrometers or less, more preferably 5 micrometers or more but 50 micrometers or less.

The polymerization initiator is not particularly limited and may be appropriately selected depending on the intended purpose, so long as polymerization is initiated through heat and light. Examples thereof include thermal polymerization initiators and photopolymerization initiators.

The thermal polymerization initiator is a compound that generates active species such as radicals and cations upon heating. Examples thereof include azo compounds such as 2,2′-azobisbutyronitrile (AIBN) and peroxides such as benzoyl peroxide (BPO). Examples of the thermal cationic polymerization initiator include benzenesulfonic acid ester and alkyl sulfonium salt.

Meanwhile, as the photopolymerization initiator, a photocationic polymerization initiator is preferably used in the case of the epoxy resin. When the photocationic polymerization initiator is mixed with the epoxy resin and light is emitted, the photocationic polymerization initiator is decomposed to generate an acid, and the acid induces polymerization of the epoxy resin. Then, curing reaction proceeds. The photocationic polymerization initiator has such effects that less volumetric shrinkage during curing is caused, oxygen inhibition does not occur, and storage stability is high.

Examples of the photocationic polymerization initiator include aromatic diazonium salts, aromatic iodonium salts, aromatic sulfonium salts, metallocene compounds, and silanol-aluminum complexes.

Moreover, a photoacid generator having a function of generating an acid upon irradiation of light can be also used as the polymerization initiator. The photoacid generator functions as an acid for initiating cationic polymerization. Examples of the photoacid generator include onium salts such as ionic sulfonium salt-based onium salts and ionic iodonium salt-based onium salts including a cation part and an ionic part. These may be used alone or in combination.

An amount of the polymerization initiator added may be different depending on a material to be used. The amount of the polymerization initiator is preferably 0.5 parts by mass or more but 10 parts by mass or less, more preferably 1 part by mass or more but 5 parts by mass or less, relative to the total amount of the sealing member (100 parts by mass). When the amount of the polymerization initiator added falls the aforementioned preferable range, curing appropriately proceeds, remaining uncured products can be decreased, and excessive outgas sing can be prevented.

The drying agent is also called a moisture absorbent and is a material having a function of physically or chemically adsorbing or absorbing moisture. When the sealing member includes the drying agent, it is possible to further improve moisture resistance and to decrease influence of outgas.

The drying agent is not particularly limited and may be appropriately selected depending on the intended purpose, but is preferably a particulate material. Examples of thereof include inorganic water-absorbing materials such as calcium oxide, barium oxide, magnesium oxide, magnesium sulfate, sodium sulfate, calcium chloride, silica gel, molecular sieve, and zeolite. Among them, zeolite is preferable because zeolite absorbs a large amount of moisture. These may be used alone or in combination.

The curing accelerator is also called a curing catalyst and is a material that accelerates curing speed. The curing accelerator is mainly used for a heat curable epoxy resin.

The curing accelerator is not particularly limited and may be appropriately selected depending on the intended purpose. Examples thereof include: tertiary amine or tertiary amine salts such as DBU (1,8-diazabicyclo(5,4,0)-undecene-7) and DBN (1,5-diazabicyclo(4,3,0)-nonene-5); imidazole-based compounds such as 1-cyanoethyl-2-ethyl-4-methylimidazole and 2-ethyl-4-methylimidazole; and phosphine or phosphonium salts such as triphenylphosphine and tetraphenylphosphonium—tetraphenyl borate. These may be used alone or in combination.

The coupling agent is not particularly limited and may be appropriately selected depending on the intended purpose, so long as it is a material having an effect of increasing molecular binding force. Examples thereof include silane coupling agents. Specific examples thereof include: silane coupling agents, such as 3-glycidoxypropyltrimethoxysilane, 3-glycidoxypropylmethyldimethoxysilane, 3-glycidoxypropylmethyldimethoxysilane, 2-(3,4-epoxycyclohexyl)ethyltrimethoxysilane, N-phenyl-γ-aminopropyltrimethoxysilane, N-(2-aminoethyl)3-aminopropylmethyldimethoxysilane, N-(2-aminoethyl)3-aminopropylmethyltrimethoxysilane, 3-aminopropyltriethoxysilane, 3-mercaptopropyltrimethoxysilane, vinyltrimethoxysilane, N-(2-(vinylbenzylamino)ethyl)3-aminopropyltrimethoxysilane hydrochloride, and 3-methacryloxypropyltrimethoxysilane. These may be used alone or in combination.

As the sealing member, epoxy resin compositions that are commercially available as sealing materials, seal materials, or adhesives have been known, and such commercially available products can be effectively used in the present disclosure. Among them, there are also epoxy resin compositions that are developed and are commercially available to be used in solar cells or organic EL elements, and such commercially available products can be particularly effectively used in the present disclosure. Examples of the commercially available epoxy resin compositions include: TB3118, TB3114, TB3124, and TB3125F (available from ThreeBond); World Rock 5910, World Rock 5920, and World Rock 8723 (available from Kyoritsu Chemical Co., Ltd.); and WB90US(P) (available from MORESCO Corporation).

In the present disclosure, a sealing sheet material may be used as the sealing material.

The sealing sheet material is a material where an epoxy resin layer has been formed on a sheet in advance. In the sheet, glass or a film having high gas barrier properties is used. A sealing member and a second substrate can be formed at once by bonding the sealing sheet material onto the second substrate, followed by curing. A structure having a hollow part can be formed depending on a formation pattern of the epoxy resin layer formed on the sheet.

A method for forming the sealing member is not particularly limited and may be appropriately selected depending on the intended purpose. Examples thereof include a dispensing method, a wire bar method, a spin coating method, a roller coating method, a blade coating method, and a gravure coating method. Moreover, as a method for forming the sealing member, methods such as relief printing, offset printing, gravure printing, intaglio printing, rubber plate printing, and screen printing may be used.

Moreover, a passivation layer may be disposed between the sealing member and the second electrode. The passivation layer is not particularly limited and may be appropriately selected depending on the intended purpose, so long as the passivation layer is disposed in such a manner that the sealing member is not in contact with the second electrode. Examples thereof include aluminum oxide, silicon nitride, and silicon oxide.

<Other Members>

Other members are not particularly limited and may be appropriately selected depending on the intended purpose.

Hereinafter, one embodiment for conducting the present disclosure will be described with reference to drawings. In each drawing, the same reference numeral is given to the same component, and redundant description may be omitted.

<Configuration of Solar Cell Module>

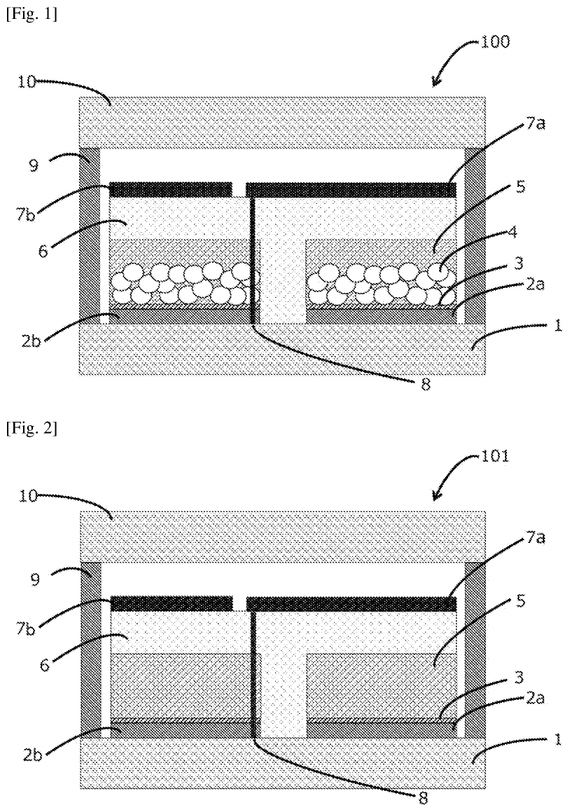

FIG. 1 is a cross-sectional view illustrating one example of a cross-sectional structure of a solar cell module of the present disclosure. As presented in FIG. 1, a solar cell module 100 includes a photoelectric conversion element that includes, on a first substrate 1, a first electrode 2, a compact electron transport layer (compact layer) 3, a porous electron transport layer (porous layer) 4, a perovskite layer 5, a hole transport layer 6, and a second electrode 7. Note that, the first electrode 2 and the second electrode 7 have a path configured to pass current to an electrode extraction terminal. Moreover, in the solar cell module 100, the second substrate 10 is disposed so as to face the first substrate 1, so that the first substrate 1 and the second substrate 10 sandwich the photoelectric conversion elements. A sealing member 9 is disposed between the first substrate 1 and the second substrate 10.

In the solar cell module 100, within a photoelectric conversion element a including a first electrode 2a and a second electrode 7a and a photoelectric conversion element b including a first electrode 2b and a second electrode 7b, first electrodes 2, compact layers 3, porous layers 4, and perovskite layers 5 are separated by hole transport layers 6 that are continuous with each other between the photoelectric conversion element a and the photoelectric conversion element b. Because this configuration can separate the porous titanium oxide layer (electron transport layer) and the perovskite layer in the solar cell module 100, less recombination of electrons through diffusion is caused, which makes it possible to maintain power generation efficiency even after exposure to light having a high illuminance for a long period of time.

The photoelectric conversion element of the solar cell module 100 is sealed with the first substrate 1, the sealing member 9, and the second substrate 10. Therefore, it is possible to control an amount of moisture and a concentration of oxygen in a hollow part existing between the second electrode 7 and the second substrate 10. By controlling the amount of moisture and the concentration of oxygen in the hollow part of the solar cell module 100, the power generation performance and the durability can be improved. That is, when the solar cell module further includes: the second substrate that is disposed so as to face the first substrate, so that the first substrate and the second substrate sandwich the photoelectric conversion elements; and the sealing member disposed between the first substrate and the second substrate and seals the photoelectric conversion elements, it is possible to control the amount of moisture and the concentration of oxygen in the hollow part, which can improve the power generation performance and the durability.

The concentration of oxygen in the hollow part is not particularly limited and may be appropriately selected depending on the intended purpose. However, the concentration thereof is preferably 0% or more but 21% or less, more preferably 0.05% or more but 10% or less, still more preferably 0.1% or more but 5% or less.

In the solar cell module 100, the second electrode 7 and the second substrate 10 are not in contact with each other. Therefore, it is possible to prevent the second electrode 7 from being peeled and being broken.

Moreover, the solar cell module 100 includes a through part 8 configured to electrically connect the photoelectric conversion element a with the photoelectric conversion element b. In the solar cell module 100, the photoelectric conversion element a and the photoelectric conversion element b are connected to each other in series, by electrically connecting the second electrode 7a of the photoelectric conversion element a with the first electrode 2b of the photoelectric conversion element b by the through part 8 penetrating through the hole transport layer 6. As described above, when a plurality of photoelectric conversion elements are connected in series, the open-circuit voltage of the solar cell module can be increased.

Note that, the through part 8 may penetrate through the first electrode 2 to reach the first substrate 1. Alternatively, the through part 8 may not reach the first substrate 1 by stopping the processing inside the first electrode 2. In the case where a shape of the through part 8 is a fine pore that penetrates through the first electrode 2 to reach the first substrate 1, when a total opening area of the fine pore is too large relative to an area of the through part 8, a decreased cross-sectional area of the film of the first electrode 2 results in an increased resistance value, which may cause reduction in a photoelectric conversion efficiency. Therefore, a ratio of an opening area of the fine pore to an area of the through part 8 is preferably 5/100 or more but 60/100 or less.

Moreover, a method for forming the through part is not particularly limited and may be appropriately selected depending on the intended purpose. Examples thereof include a sand blasting method, a water blasting method, a chemical etching method, a laser processing method, and a method using abrasive paper. Among them, the laser processing method is preferable because the fine pore can be formed without using sand, etching, and resist and this makes it possible to process the fine pore in clean and reproducible manners. Furthermore, the reason why the laser processing method is preferable is as follows. Specifically, when the through part 8 is formed, it is possible to remove at least one of the compact layer 3, the porous layer 4, the perovskite layer 5, the hole transport layer 6, and the second electrode 7 through impact peeling using the laser processing method. Therefore, it is not necessary to provide a mask during lamination, and removal of the materials forming the photoelectric conversion element and formation of the through part can be easily performed at one time.

Here, a distance between the perovskite layer in the photoelectric conversion element a and the perovskite layer in the photoelectric conversion element b is preferably 1 micrometer or more but 100 micrometers or less, more preferably 5 micrometers or more but 50 micrometers or less. When the distance between the perovskite layer in the photoelectric conversion element a and the perovskite layer in the photoelectric conversion element b is 1 micrometer or more but 100 micrometers or less, the porous titanium oxide layer (electron transport layer) and the perovskite layer are separated, and less recombination of electrons through diffusion is caused, which makes it possible to maintain power generation efficiency even after exposure to light having a high illuminance for a long period of time. That is, when a distance between the perovskite layer in one photoelectric conversion element and the perovskite layer in the other photoelectric conversion element within at least two photoelectric conversion elements adjacent to each other is 1 micrometer or more but 100 micrometers or less, it is possible to maintain power generation efficiency even after exposure to light having a high illuminance for a long period of time.

Here, the phrase “distance between the perovskite layer in one photoelectric conversion element and the perovskite layer in the other photoelectric conversion element within at least two photoelectric conversion elements adjacent to each other” means the shortest distance among distances between peripheries (end parts) of the perovskite layers in the photoelectric conversion elements.

FIG. 2 is a cross-sectional view illustrating another example of a cross-sectional structure of the solar cell module of the present disclosure. As presented in FIG. 2, a solar cell module 101 is different from the solar cell module 100 because the photoelectric conversion element has no porous layer 4. That is, the photoelectric conversion element in the solar cell module of the present disclosure may not include the porous layer 4.

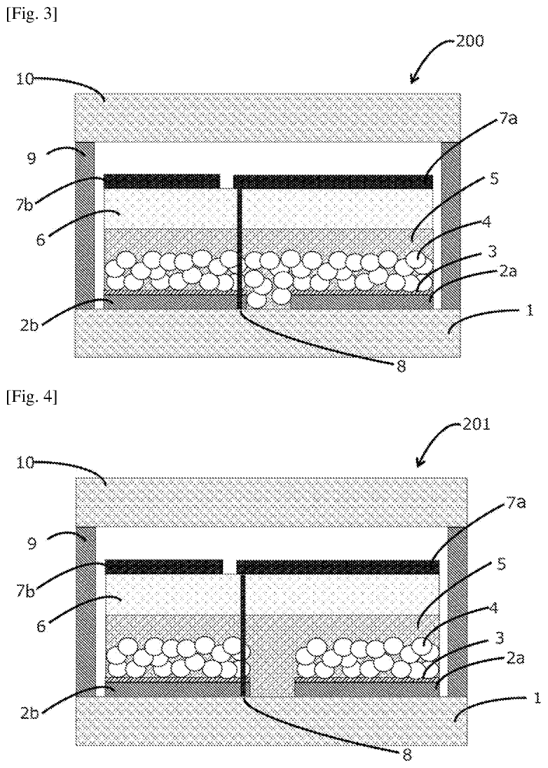

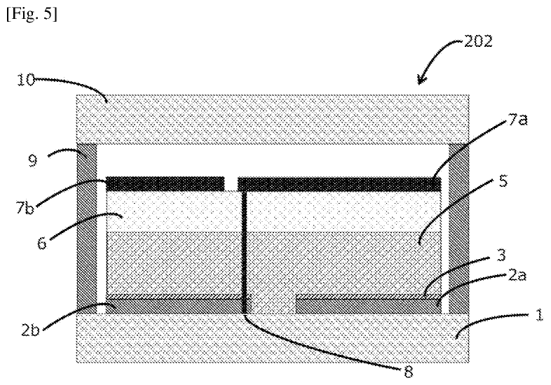

FIG. 3 is a cross-sectional view illustrating one example of a cross-sectional structure of a solar cell module of Comparative Example of the present disclosure. FIG. 4 and FIG. 5 are cross-sectional views illustrating other examples of cross-sectional structures of solar cell modules of Comparative Examples of the present disclosure. As presented in FIG. 3 to FIG. 5, in addition to the hole transport layers 6, the perovskite layers 5 are continuous with each other, much recombination of electrons is caused and thus the efficiency is decreased. As a result, the power generation efficiency cannot be maintained.

The solar cell module of the present disclosure can be applied to power source devices by using it in combination with, for example, a circuit board configured to control generated electric current. Examples of the devices using such a power source device include electronic calculators and watches. In addition, the power source device including the photoelectric conversion element of the present disclosure can be applied to, for example, mobile phones, electronic notebooks, and electronic paper. The power source device including the solar cell module of the present disclosure can be used as an auxiliary power supply configured to prolong a continuously operating time of rechargeable electrical appliances or battery-type electrical appliances, or as a power source that can be used in the nighttime by using it in combination with a secondary battery. Moreover, the solar cell module of the present disclosure can be used in IoT devices or artificial satellites as self-supporting power supplies that require neither replacement of battery nor power source wirings.

### EXAMPLES

The present disclosure will be described in more detail by way of Examples and Comparative Examples. The present disclosure should not be construed as being limited to these Examples.

### Example 1

<Production of Solar Cell Module>

First, a liquid obtained by dissolving, in isopropyl alcohol (10 ml), titanium diisopropoxide bis(acetylacetone) isopropyl alcohol solution (75%) (0.36 g) was coated on an FTO glass substrate through the spin coating method. The coating liquid was dried at 120 degrees Celsius for 3 minutes and was baked at 450 degrees Celsius for 30 minutes to produce a first electrode and a compact electron transport layer (compact layer) on the first substrate. Note that, the compact layer was set to have an average thickness of 10 micrometers or more but 40 micrometers or less.

Next, a dispersion liquid obtained by diluting titanium oxide paste (available from Greatcell Solar Limited, product name: MPT-20) with a terpineol was coated on the compact layer through the spin coating method. Then, the resultant was dried at 120 degrees Celsius for 3 minutes and was baked at 550 degrees Celsius for 30 minutes. Then, a 0.1 M (note that, M means mol/dm³) acetonitrile solution that had dissolved lithium bis(trifluoromethanesulfonyl)imide (available from KANTO CHEMICAL CO., INC., product number: 38103) was coated on the aforementioned film through the spin coating method and was baked at 450 degrees Celsius for 30 minutes to produce a porous electron transport layer (porous layer). Here, the porous layer was set to have an average thickness of 150 nm.

Lead(II) iodide (0.5306 g), lead(II) bromide (0.0736 g), methylamine bromide(0.0224 g), formamidine iodide (0.1876 g), and potassium iodide (0.0112 g) were added to N,N-dimethylformamide (0.8 ml) and dimethyl sulfoxide (0.2 ml), and the resultant was heated and stirred at 60 degrees Celsius, to thereby obtain a solution. The solution was coated on the above porous layer through the spin coating method while chlorobenzene (0.3 ml) was added dropwise thereto to form a perovskite film. Then, the perovskite film was dried at 150 degrees Celsius for 30 minutes to produce a perovskite layer. Note that, the perovskite layer was set to have an average thickness of 300 nm.

The laminate obtained by the above steps was subjected to laser processing to form a groove where a distance between the adjacent laminates was 10 micrometers. Next, a chlorobenzene solution that had dissolved 2,2(7,7(-tetrakis-(N,N-di-p-methoxyphenylamine)9,9(-spirobifluorene))) (which may be referred to as spiro-OMeTAD) (0.12 M), lithium bis(trifluoromethanesulfonyl)imide (0.034 M), 4-t-butylpyridine (0.1 M), and tris(2-(1H-pyrazol-1-yl)-4-tert-butylpyridine) cobalt(III) hexafluorophosphate (1.6 wt % vs spiro-OMeTAD) was coated on the laminate obtained by the above steps through the spin coating method, to thereby produce a hole transport layer. Note that, an average thickness of the hole transport layer (portion on the perovskite layer) was set to be 100 nm.

Moreover, 100 nm of gold was deposited on the above laminate under vacuum.

End parts of the first substrate and the second substrate provided with sealing members were subjected to an etching treatment through laser processing and then were subjected to laser processing to form through holes (conduction parts) for connecting photoelectric conversion elements in series. Next, silver was deposited on the above laminate under vacuum to thereby form a second electrode having a thickness of about 100 mn. The mask film formation caused a distance between adjacent second electrodes to be 200 micrometers. Silver was also deposited on the inner walls of the through holes, and it was confirmed that the adjacent photoelectric conversion elements were connected in series. The number of the photoelectric conversion elements disposed in series was 6.

Then, an ultraviolet curable resin (available from ThreeBond Holdings Co., Ltd., product name: TB3118) was coated with a dispenser (available from SAN-EI TECH Ltd., product name: 2300N) on end parts of the first substrate so that the photoelectric conversion elements (power generation regions) were surrounded. Then, it was transferred to a glove box that had been controlled to have a low humidity (dew point −30 degrees Celsius) and a concentration of oxygen of 0.5%. Then, a cover glass as the second substrate was disposed on the ultraviolet curable resin and the ultraviolet curable resin was cured through ultraviolet irradiation to seal the power generation regions. As a result, the solar cell module 1 of the present disclosure as exemplified in FIG. 1 was produced. Each distance between layers constituting the photoelectric conversion elements adjacent to each other is presented in Table 1.

<Evaluation of Solar Cell Module>

While the solar cell module 1 obtained was irradiated with light by a solar simulator (AM1.5, 10 mW/cm²), the solar cell module 1 obtained was evaluated for characteristics of the solar cell (initial characteristics) using a solar cell evaluation system (available from NF Corporation, product name: As-510-PV03). Furthermore, after the above solar simulator was used to continuously emit light for 100 hours under the aforementioned conditions, the characteristics of the solar cell (characteristics after continuous irradiation for 100 hours) were evaluated in the same manner as described above.

The evaluated characteristics of the solar cell are the open-circuit voltage, the short-circuit current density, the shape factor, and the conversion efficiency (power generation efficiency). A rate of the conversion efficiency in the characteristics after continuous irradiation for 100 hours relative to the conversion efficiency in the initial characteristics was determined as a maintenance rate of the conversion efficiency. Results thereof are presented in Table 2.

### Example 2

A solar cell module 2 illustrated in FIG. 2 was produced in the same manner as in Example 1 except that the first electrodes, the compact layers, the porous layers, and the perovskite layers in the photoelectric conversion elements adjacent to each other were set to have a distance of 40 micrometers. Each distance between the layers constituting the photoelectric conversion elements adjacent to each other is presented in Table 1. The solar cell module 2 was evaluated in the same manner as in Example 1. Evaluation results are presented in Table 2.

### Example 3

A solar cell module 3 was produced in the same manner as in Example 1 except that the chlorobenzene solution was changed to a chlorobenzene solution that had dissolved poly(3-n-hexyl)thiophene (which may be referred to as P3HT hereinafter) (0.02 M), lithium bis(trifluoromethanesulfonyl)imide (5.7 mM), 4-t-butylpyridine (0.017 M), tris(2-(1H-pyrazol-1-yl)-4-tert-butylpyridine) cobalt(III) hexafluorophosphate (1.6 wt % vs P3HT). Each distance between the layers constituting the photoelectric conversion elements adjacent to each other is presented in Table 1. The solar cell module 3 was evaluated in the same manner as in Example 1. Evaluation results are presented in Table 2.

### Example 4

A solar cell module 4 illustrated in FIG. 2 was produced in the same manner as in Example 1 except that no porous layer was formed in Example 1. Each distance between the layers constituting the photoelectric conversion elements adjacent to each other is presented in Table 1. The solar cell module 4 was evaluated in the same manner as in Example 1. Evaluation results are presented in Table 2.

### Example 5

A solar cell module 5 was produced in the same manner as in Example 4 except that the compact layer was changed to a compact layer formed of tin oxide that was formed through sputtering. Each distance between the layers constituting the photoelectric conversion elements adjacent to each other is presented in Table 1. The solar cell module 5 was evaluated in the same manner as in Example 1. Evaluation results are presented in Table 2.

### Example 6

A solar cell module 6 was produced in the same manner as in Example 5 except that cesium iodide (0.0143 g) was further used in addition to lead(II) iodide (0.5306 g), lead(II) bromide (0.0736 g), methylamine bromide (0.0224 g), formamidine iodide (0.1876 g), and potassium iodide (0.0112 g), which were used for forming the perovskite layer in Example 5. Each distance between the layers constituting the photoelectric conversion elements adjacent to each other is presented in Table 1. The solar cell module 6 was evaluated in the same manner as in Example 1. Evaluation results are presented in Table 2.

### Comparative Example 1

A solar cell module 7 illustrated in FIG. 3 was produced in the same manner as in Example 1 except that the porous layer and the perovskite layer were in a state of a continuous layer. Each distance between the layers constituting the photoelectric conversion elements adjacent to each other is presented in Table 1. The solar cell module 7 was evaluated in the same manner as in Example 1. Evaluation results are presented in Table 2.

### Comparative Example 2

A solar cell module 8 illustrated in FIG. 3 was produced in the same manner as in Example 1 except that the first electrodes and the compact layers in the photoelectric conversion elements adjacent to each other were set to have a distance of 40 micrometers, and the porous layer and the perovskite layer were in a state of a continuous layer. Each distance between the layers constituting the photoelectric conversion elements adjacent to each other is presented in Table 1. The solar cell module 8 was evaluated in the same manner as in Example 1. Evaluation results are presented in Table 2.

### Comparative Example 3

A solar cell module 9 illustrated in FIG. 4 was produced in the same manner as in Example 1 except that the first electrodes, the compact layers, and the porous layers in the photoelectric conversion elements adjacent to each other were set to have a distance of 40 micrometers, and the perovskite layer was in a state of a continuous layer. Each distance between the layers constituting the photoelectric conversion elements adjacent to each other is presented in Table 1. The solar cell module 9 was evaluated in the same manner as in Example 1. Evaluation results are presented in Table 2.

TABLE 1

| | | | | | | Hole | |
|---|---|---|---|---|---|---|---|
| | | First | Compact | Porous | Perovskite | transport | Second |
| | Solar cell | electrode | layer | layer | layer | layer | electrode |
| | module | (μm) | (μm) | (μm) | (μm) | (μm) | (μm) |
| Example 1 | 1 | 10 | 10 | 10 | 10 | Continuous | 200 |
| Example 2 | 2 | 40 | 40 | 40 | 40 | Continuous | 200 |
| Example 3 | 3 | 10 | 10 | 10 | 10 | Continuous | 200 |
| Example 4 | 4 | 10 | 10 | — | 10 | Continuous | 200 |
| Example 5 | 5 | 10 | 10 | — | 10 | Continuous | 200 |
| Example 6 | 6 | 10 | 10 | — | 10 | Continuous | 200 |
| Comparative | 7 | 10 | 10 | Continuous | Continuous | Continuous | 200 |
| Example 1 | | | | | | | |
| Comparative | 8 | 40 | 40 | Continuous | Continuous | Continuous | 200 |
| Example 2 | | | | | | | |
| Comparative | 9 | 40 | 40 | 40 | Continuous | Continuous | 200 |
| Example 3 | | | | | | | |

TABLE 2

| | | | | | | Characteristics after continous | | | | |
|---|---|---|---|---|---|---|---|---|---|---|
| | | Initial characteristics | | | | irradiation for 100 hours | | | | Maintenance |
| | | Open- | Short-circuit | | | Open- | Short-circuit | | | rate of |
| | Solar | circuit | current | | Conversion | circuit | current | | Conversion | conversion |
| | cell | voltage | density | Shape | efficiency | voltage | density | Shape | efficiency | efficiency |
| | module | (V) | (mA/cm²) | factor | (%) | (V) | (mA/cm2) | factor | (%) | (%) |
| Example 1 | 1 | 6.12 | 3.30 | 0.65 | 13.1 | 6.06 | 3.15 | 0.64 | 12.2 | 93.1 |
| Example 2 | 2 | 6.18 | 3.35 | 0.64 | 13.2 | 6.11 | 3.32 | 0.64 | 13.0 | 98.5 |
| Example 3 | 3 | 6.04 | 3.29 | 0.66 | 13.1 | 5.97 | 3.26 | 0.65 | 12.7 | 96.9 |
| Example 4 | 4 | 6.28 | 3.33 | 0.63 | 13.3 | 6.09 | 3.29 | 0.63 | 12.6 | 94.7 |
| Example 5 | 5 | 6.01 | 3.44 | 0.64 | 13.2 | 5.89 | 3.39 | 0.64 | 12.8 | 97.0 |
| Example 6 | 6 | 6.04 | 3.42 | 0.63 | 13.0 | 5.85 | 3.33 | 0.63 | 12.3 | 94.6 |
| Comparative | 7 | 6.05 | 3.28 | 0.64 | 12.7 | 5.76 | 2.88 | 0.59 | 9.8 | 77.2 |
| Example 1 | | | | | | | | | | |
| Comparative | 8 | 6.11 | 3.32 | 0.65 | 13.3 | 5.69 | 2.91 | 0.58 | 9.6 | 72.2 |
| Example 2 | | | | | | | | | | |
| Comparative | 9 | 6.15 | 3.36 | 0.63 | 13.0 | 5.51 | 2.98 | 0.60 | 9.7 | 74.6 |
| Example 3 | | | | | | | | | | |

From the results in Table 2, it was found that the solar cell modules of Examples 1 to 6 could maintain power generation efficiency even after exposure to light having a high illuminance for a long period of time, compared to those of Comparative Examples 1 to 3.

As described above, in the solar cell module of the present disclosure, the hole transport layers are continuous with each other within at least two photoelectric conversion elements adjacent to each other, and the first electrodes, the electron transport layers, and the perovskite layers are separated by the hole transport layer within at least two photoelectric conversion elements adjacent to each other. As a result, the solar cell module of the present disclosure can maintain power generation efficiency even after exposure to light having a high illuminance for a long period of time.

Aspects of the present disclosure are as follows, for example.

<1> A solar cell module including:

a substrate; and

a plurality of photoelectric conversion elements disposed on the substrate, each of the plurality of photoelectric conversion elements including a first electrode, an electron transport layer, a perovskite layer, a hole transport layer, and a second electrode,

wherein, within at least two of the photoelectric conversion elements adjacent to each other, the hole transport layers are continuous with each other, and

the first electrodes, the electron transport layers, and the perovskite layers are separated by the hole transport layer within the at least two of the photoelectric conversion elements adjacent to each other.

<2> The solar cell module according to <1>,

wherein, within the at least two of the photoelectric conversion elements adjacent to each other, the first electrode in one photoelectric conversion element and the second electrode in other photoelectric conversion element are electrically connected to each other through a conduction part penetrating through the hole transport layer.

<3> The solar cell module according to <1> or <2>,

wherein the electron transport layer includes a porous layer including titanium oxide particles.

<4> The solar cell module according to any one of <1> to <3>,

wherein the hole transport layer includes a plurality kinds of compounds.

<5> The solar cell module according to any one of <1> to <4>, further including:

when the substrate is defined as a first electrode, a second substrate disposed so as to face the first substrate, so that the first substrate and the second substrate sandwich the photoelectric conversion elements; and

a sealing member that is disposed between the first substrate and the second substrate and seals the photoelectric conversion elements.

<6> The solar cell module according to any one of <1> to <5>,

wherein, within the at least two of the photoelectric conversion elements adjacent to each other,

a distance between the perovskite layer in one photoelectric conversion element and the perovskite layer in other photoelectric conversion element is 1 micrometer or more but 40 micrometers or less.

According to the solar cell module according to any one of <1> to <6>, it is possible to solve the existing problems in the art and to achieve the object of the present disclosure.

### REFERENCE SIGNS LIST

1: substrate (first substrate)
2, 2a, 2b: first electrode
3: compact electron transport layer (compact layer)
4: porous electron transport layer (porous layer)
5: perovskite layer
6: hole transport layer
7, 7a, 7b: second electrode
8: through part (conduction part)
9: sealing member
10: second substrate
100: solar cell module
101: solar cell module

1. A solar cell module comprising:
a substrate; and
a plurality of photoelectric conversion elements disposed on the substrate, each of the plurality of photoelectric conversion elements including a first electrode, an electron transport layer, a perovskite layer, a hole transport layer, and a second electrode,
wherein, within at least two of the photoelectric conversion elements adjacent to each other, the hole transport layers are continuous with each other, and
the first electrodes, the electron transport layers, and the perovskite layers are separated by the hole transport layer within the at least two of the photoelectric conversion elements adjacent to each other.

2. The solar cell module according to claim 1,
wherein, within the at least two of the photoelectric conversion elements adjacent to each other, the first electrode in one photoelectric conversion element and the second electrode in other photoelectric conversion element are electrically connected to each other through a conduction part penetrating through the hole transport layer.

3. The solar cell module according to claim 1,
wherein the electron transport layer includes a porous layer including titanium oxide particles.

4. The solar cell module according to claim 1,
wherein the hole transport layer includes a plurality kinds of compounds.

5. The solar cell module according to claim 1, further comprising:
when the substrate is defined as a first electrode, a second substrate disposed so as to face the first substrate, so that the first substrate and the second substrate sandwich the photoelectric conversion elements; and
a sealing member that is disposed between the first substrate and the second substrate and seals the photoelectric conversion elements.

6. The solar cell module according to claim 1,
wherein, within the at least two of the photoelectric conversion elements adjacent to each other,
a distance between the perovskite layer in one photoelectric conversion element and the perovskite layer in other photoelectric conversion element is 1 micrometer or more but 100 micrometers or less.
